(19) United States
(12) Patent Application Publication
(10) Pub. No.: US 2026/0164756 A1
(43) Pub. Date: Jun. 11, 2026

(54) GATE STRUCTURE AND GATE CONTACT FOR GATE-ALL-AROUND FIELD EFFECT TRANSISTORS WITH TOP HARDMASK

(71) Applicant: Taiwan Semiconductor Manufacturing Company, Ltd., Hsinchu (TW)

(72) Inventors: Peng-Soon LIM, Kluang Johor (MY); Huang-Lin CHAO, Hsinchu City (TW); Pinyen LIN, Rochester, NY (US)

(73) Assignee: Taiwan Semiconductor Manufacturing Company, Ltd., Hsinchu (TW)

(21) Appl. No.: 18/972,339

(22) Filed: Dec. 6, 2024

(51) Int. Cl. H10D 64/66; H10D 30/00; H10D 30/01; H10D 64/01

(52) U.S. Cl. CPC H10D 64/669; H10D 30/0191; H10D 30/502; H10D 64/01

(57) ABSTRACT

This disclosure is directed to a structure of a semiconductor device and a method of forming the structure. The structure can include a gate-all-around field effect transistor (GAAFET) on a substrate. The GAAFET can include a stack of channel layers and a mask layer on the channel layers. The GAAFET can further include a gate structure with gate electrodes surrounding each of the channel layers and the mask layer. The gate structure can further include a barrier layer between the gate electrodes. The GAAFET can further include a gate contact via through the mask layer in contact with a portion of the barrier layer between the mask layer and the stack of channel layers. During the formation of the gate contact via, the presence of the barrier layer can prevent an oxidation of the gate electrodes surrounding each of the channel layers.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1A is an isotropic view of a semiconductor device including semiconductor transistors, in accordance with some embodiments.

FIGS. 1B and 1C are cross-sectional views of a semiconductor device including semiconductor transistors, in accordance with some embodiments.

FIG. 2 is a flowchart of a method for the formation of a semiconductor transistor, in accordance with some embodiments.

FIGS. 3 and 4 are isometric views of intermediate structures during the fabrication of a semiconductor transistor, in accordance with some embodiments.

FIGS. 5 through 8, 9A, 9B, 10A, 10B, 11A, 11B, 12A, 12B, 13A, and 13B are cross-sectional views of intermediate structures during the fabrication of a semiconductor transistor, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

By way of example and not limitation, nanostructure transistors, like GAA nano-sheet (NS) or nano-wire (NW) FETs (collectively referred to as “GAAFETs”) with nanostructure (such as nano-sheet (NS) or nano-wire (NW)) channel regions, can be formed as follows. A fin-like structure with alternating silicon-germanium (SiGe) and silicon (Si) NS or NW layers is formed on a substrate (e.g., on semiconductor substrate). A sacrificial gate structure is then formed on a middle portion of the fin-like structure to cover top and sidewall surfaces of the fin-like structure so that edge portions of the fin-like structure are not covered by the sacrificial gate structure. The edge portions of the fin-like structure not covered by the sacrificial gate structure are removed. Subsequently, edge portions of the SiGe NS or NW layers are recessed with respect to edge portions of the Si NS or NW layers, and an inner spacer structure is formed by depositing a dielectric material to fill the space formed by the etched portions of the SiGe NS or NW layers. Source/drain (S/D) epitaxial structures are then formed to abut (or to be in contact with) edge portions of the fin-like structures so that the S/D epitaxial structures are in contact with the Si NS or NW layers and isolated (or separated) from the SiGe NS or NW layers by the inner spacer structures. Source/drain may refer to a source or a drain, individually or collectively dependent upon the context. In a subsequent operation, the sacrificial gate structure is removed to expose the top and sidewall surfaces of the fin-like structure. The SiGe NS or NW layers are selectively removed from the fin-like structure. During the selective removal process, the Si NS or NW layers and the inner spacer structures are not removed. Subsequently, a metal gate structure is formed to surround the Si NS or NW layers. Similar to the SiGe NS or NW layers prior to their selective removal, the metal gate structure is isolated (or separated) from the S/D epitaxial structures through the inner spacer structures.

The structure of the GAAFETs may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

As semiconductor devices continue scaling down, in the exemplary GAAFET formed by the process described above, critical dimensions of the GAAFET, such as lengths/widths of the Si NS or NW layers as channels and the gate structure are getting smaller. Accordingly, forming the gate structure with reliable performance becomes increasingly challenging. For example, as higher aspect ratio (e.g., a ratio of a height to a width) of the gate structure results in stronger parasitic coupling with surrounding conductive elements (e.g., the contact structure with the S/D epitaxial structures). A large height of the gate structure with respect to its width can also increase the resistance of the gate structure, which can further impact the performance of the semiconductor device, such as its speed of operation. One approach to tackle the above challenges is to implement a top hardmask (HM) formed as a topmost layer of the fin-like structure and over the Si and SiGe NS or NW layers. Accordingly, the gate structure is formed surrounding the Si NS or NW layers as well as the mask layer. Subsequently, a gate contact can be formed through the mask layer and in contact with a portion of the gate structure between the mask layer and a topmost Si NS or NW layer. Therefore, the presence of the mask layer defines an upper boundary of the gate structure, such that the height of the gate structure is significantly reduced compared with the scheme without the top HM. However, the top HM scheme can introduce issues that may compromise the reliability of the gate structure. In particular, forming the gate contact requires etching through the mask layer, during which a portion of the gate structure can be oxidized once exposed to air. The contact formed between the gate contact and the oxidized portion of the gate structure can cause high contact resistance and high threshold voltage, especially for GAAFETs using n-type work function metals as gate electrodes in the gate structure.

The embodiments described herein are directed to address the challenges mentioned above. In some embodiments, a structure of a semiconductor device can include a fin structure, which can include nanostructures as channels and a mask layer on the nanostructures. The structure can further include a gate structure and a gate contact. The gate structure can include high-k dielectric layers and work function metal layers surrounding the mask layer and each of the nanostructures. The gate structure can further include a barrier layer between the work function metal layers. The gate contact can protrude through the mask layer and can be in contact with a portion of the barrier layer under the mask layer and above the nanostructures. The structure can further include source/drain regions adjacent to the nanostructures and inner spacers between the source/drain regions and the gate structure. In some embodiments, a method of forming the structure can include forming the gate structure by depositing the barrier layer between the work function metal layers. The method can further include forming the gate contact by forming an opening through the mask layer and a portion of the high-k dielectric layer under the mask layer, using tungsten chloride (WClₓ, such as tungsten(V) chloride (WCl₅)) and hydrogen (H₂) as precursors to deposit tungsten in the opening while removing an oxidized portion of the work function metal layer in the opening. During the process of forming the gate contact, the presence of the barrier layer can prevent further oxidation of the work function metal layers surrounding the nanostructures and can preserve a low resistivity of the work function metal layers. The removal of the oxidized portion can further ensure a high conductivity of the contact between the gate contact and the gate structure.

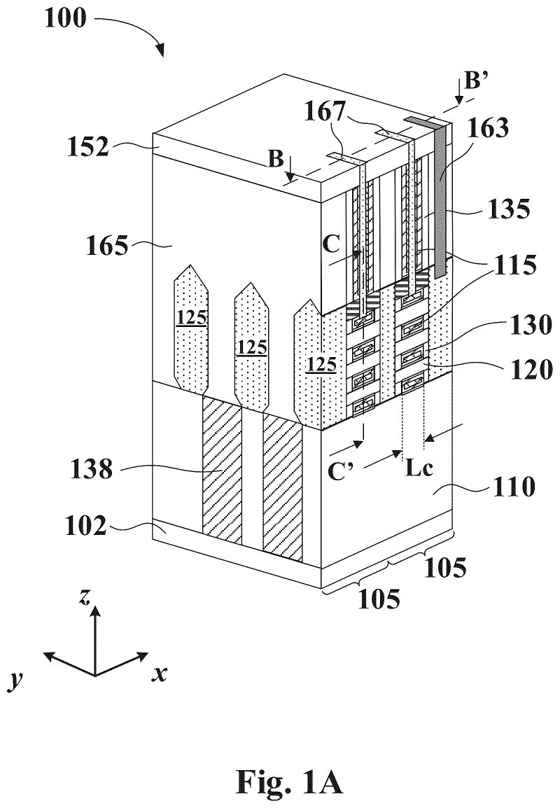

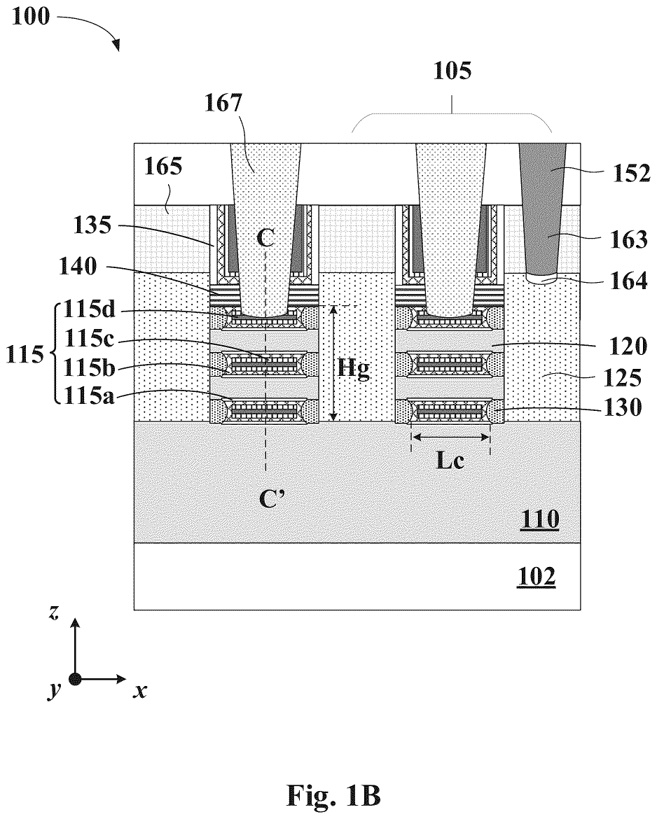

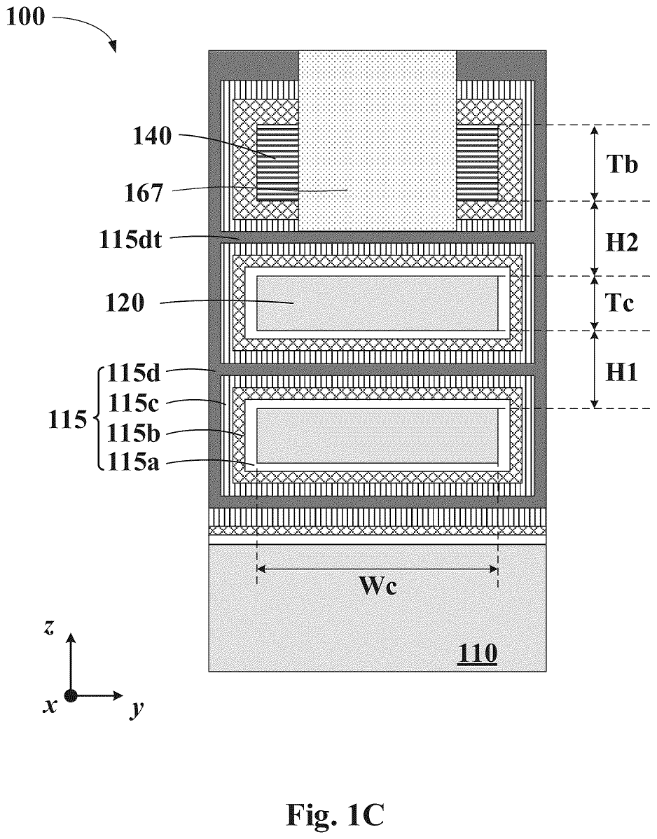

A semiconductor device 100 having multiple transistors 105 formed over a substrate 102 is described with reference to FIGS. 1A-1C, according to some embodiments. Semiconductor device 100 can be included in a microprocessor, memory cell, or other integrated circuit (IC). FIG. 1A illustrates an isotropic view of semiconductor device 100. FIG. 1B illustrates a cross-sectional (e.g., along the x-z plane) view of semiconductor device 100 along line B-B′ of FIG. 1A. FIG. 1C illustrates a cross-sectional (e.g., along the y-z plane) view of semiconductor device 100 along line C-C′ of FIG. 1A.

Referring to FIG. 1A, substrate 102 can be a semiconductor material, such as silicon. In some embodiments, substrate 102 can include a crystalline silicon substrate (e.g., wafer). In some embodiments, substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped depending on design requirements (e.g., p-type substrate or n-type substrate). In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111).

Although FIG. 1A shows fin structure 110 accommodating two transistors 105, any number of transistors 105 can be disposed along fin structure 110. In some embodiments, transistors 105 can include multiple fin structures 110 extending along a first horizontal direction (e.g., in the x-direction) and gate structure 115 traversing through the multiple fin structures 110 along a second horizontal direction (e.g., in the y-direction). In some embodiments, a crystal orientation of fin structures 110 can be the same as the crystal orientation of substrate 102.

Referring to FIGS. 1A-1C, one or more nano-sheet (NS) layers 120 can be disposed over fin structure 110. Each NS layer 120 can be wrapped by gate structure 115 to function as transistor 105's channel. For example, a top surface, side surfaces, and a bottom surface of each NS layer 120 can be surrounded and in physical contact with gate structure 115. Fin structure 110 and NS layers 120 can be made of materials similar to (e.g., lattice mismatch within about 5%) substrate 102. In some embodiments, a crystal orientation of NS layers 120 can be the same as the crystal orientation of fin structures 110. In some embodiments, fin structure 110 and NS layers 120 can be made of Si or SiGe. Fin structure 110 and NS layers 120 can be un-doped, doped with p-type dopants, doped with n-type dopants, or doped with intrinsic dopants. In some embodiments, fin structure 110 and NS layers 120 can be doped together with p-type dopants or with n-type dopants. Each NS layer 120 can have a thickness Tc, representing transistor 105's channel thickness, as shown in FIG. 1C. Thickness Tc can have any suitable vertical (e.g., in the z-direction) dimension, such as from about 3 nm to about 15 nm. For example, thickness Tc can be between about 5 nm and about 8 nm. NS layers 120 can have a width Wc, representing transistor 105's channel width, as shown in FIG. 1C. Width Wc can have any suitable horizontal (e.g., in the y-direction) dimension, such as from about 5 nm to about 150 nm. For example, width Wc can be between about 15 nm and about 50 nm. In some embodiments, NS layers 120 can be vertically spaced apart by a vertical spacing H1. In some embodiments, vertical spacing H1 can be between about 3 nm and about 30 nm. For example, vertical spacing H1 can be between about 8 nm and about 12 nm. Although FIG. 1A shows that each transistor 105 includes three NS layers 120 and FIGS. 1B and 1C show that each transistor 105 includes two NS layers 120, any number of NS layers 120 can be included in each transistor 105. For example, each transistor 105 can include one, four, five, or six NS layers 120.

Referring to FIGS. 1A-1C, each transistor 105 can include a mask layer 140 disposed above NS layers 120. For example, mask layer 140 can be spaced apart from a top most NS layer 120 by a vertical spacing H2. In some embodiments, vertical spacing H2 can be substantially the same as vertical spacing H1 between NS layers 120. Mask layer can have similar dimensions as NS layers 120. For example, a width of mask layer can be substantially the same as width Wc. In some embodiments, mask layer 140 and NS layers 120 can also have substantially the same length along the x-direction. Mask layer 140 can have a thickness Tb. In some embodiments, thickness Tb and thickness Tc of NS layers 120 can be substantially the same. In some embodiments, thickness Tb can be greater than thickness Tc. Mask layer 140 can include a low-k material with a dielectric constant less than about 3.9, such as silicon carbon nitride (SiCN) or silicon oxycarbonitride (SiOCN). In some embodiments, Mask layer 140 can include a layer of silicon nitride. Mask layer 140 is also referred to as a top HM 140.

Referring to FIGS. 1A-1C, gate structure 115 can be a multilayered structure that wraps around each NS layer 120 to modulate transistor 105. For example, as shown in FIG. 1C, each NS layer 120 has its surfaces along the z-and y-directions surrounded by gate structure 115. Gate structure 115 can also wrap around mask layer 140. Gate structures 115 can have a length Lc representing transistor 105's channel length, as shown in FIGS. 1A and 1B. Length Lc can have any suitable horizontal (e.g., in the x-direction) dimension, such as from about 3 nm to about 200 nm. In some embodiments, a ratio of width Wc to length Lc can be between about 3:1 and about 10:1. For example, the ratio of width Wc to length Lc can be about 5:1. In some embodiments, a height Hg of gate structures 115 along a vertical direction (e.g., in the z-direction) can be defined as a vertical distance between fin structure 110 and mask layer 140, and can be between about 10 nm and about 100 nm.

By way of example and not limitation, each gate structure 115 can include a dielectric stack formed by interfacial dielectric layers 115a and gate dielectric layers 115b. For example, as shown in FIG. 1C, each NS layer 120 can be wrapped by an interfacial dielectric layer 115a and further by a gate dielectric layer 115b. In some embodiments, mask layer 140 can also be wrapped by a gate dielectric layer 115b. In some embodiments, an interfacial dielectric layer 115a and a gate dielectric layer 115b can also be disposed on fin structure 110 and under a bottommost NS layer 120. Gate dielectric layers 115b can include any suitable dielectric material with any suitable thickness that can provide channel modulation for transistor 105. In some embodiments, gate dielectric layer 115b can be made of silicon oxide or a high-k dielectric material (e.g., hafnium oxide or aluminum oxide). In some embodiments, gate dielectric layer 115b can have a thickness ranging from about 1 nm to about 5 nm. Based on the disclosure herein, other materials and thicknesses for gate dielectric layer 115b are within the scope and spirit of this disclosure.

Further, gate structure 115 can include gate electrodes 115c, each surrounding a gate dielectric layer 115b that surrounds a NS layer 120 or mask layer 140, as shown in FIG. 1C. In some embodiments, a gate electrode 115c can also be disposed on fin structure 110 and under the bottommost NS layer 120. Gate electrodes 115c can function as a gate terminal for transistor 105 by modulating the conductivity of NS layers 120. Each gate electrodes 115c can include one or more work function metal layers, such as n-type and/or p-type work function metal layers. For example, the n-type work function metal layers in gate electrodes 115c can include aluminum-containing metal carbide, such as titanium aluminum carbide (TiAlC), tantalum aluminum carbide (TaAlC), niobium aluminum carbide (NbAlC), titanium aluminum silicon carbide (TiAlSiC), and/or any suitable conductive material that provides a suitable work function to modulate transistor 105.

In some embodiments, gate structure 115 can further include a barrier layer 115d surrounding gate electrodes 115c, as shown in FIG. 1C. In particular, barrier layer 115d includes a barrier layer portion 115dt disposed between mask layer 140 and a topmost NS layer 120 to separate the two topmost gate electrodes 115c surrounding mask layer 140 and the topmost NS layer 120. In some embodiments, barrier layer 115d can also be disposed between adjacent gate electrodes 115c surrounding adjacent NS layers 120. In some embodiments, barrier layer 115d can also be disposed on side surfaces of gate electrodes 115c. In some embodiments, barrier layer 115d can also be disposed on fin structure 110 and under the bottommost NS layer 120. Barrier layer 140 can include a conductive material that is immune to oxidation during an etching process to mask layer 140. In some embodiments, barrier layer 115d can include titanium nitride (TiN) and/or tantalum nitride (TaN). In some embodiments, barrier layer 115d can be doped with aluminum and/or silicon. In some embodiments, a thickness of barrier layer 115d between gate electrodes 115c can be between about 1 nm and about 5 nm. As discussed in the following, the presence of barrier layer 115d can prevent the oxidation of gate electrodes 115c surrounding NS layers 120 during an etching process to form a gate contact. In some embodiments, the etching process may include fluorine-based etchants, such that fluorine atoms can vertically diffuse into barrier layer 140 from above. For example, a first concentration of fluorine atoms in barrier layer portion 115dt between mask layer 140 and the topmost NS layer 120 can be greater than a second concentration of fluorine atoms in other portions of barrier layer 115d, such as the portions between NS layers 120. In some embodiments, a ratio of the first concentration to the second concentration can be between about 2:1 and about 10:1.

Referring to FIGS. 1A-1C, each transistor 105 of semiconductor device 100 can further include a gate contact via 167 in contact with barrier layer 115d and gate electrode 115c. Gate contact via 167 can be disposed through mask layer 140 to form electrical contact with a portion of gate structure 115 under mask layer 140. Gate contact via 167 can also extend vertically through gate dielectric layer 115b and gate electrodes 115c that surround mask layer 140. In some embodiments, gate contact via 167 can be in direct contact with barrier layer portion 115dt between mask layer 140 and the topmost NS layer 120. In some embodiments, an interface between gate contact via 167 and barrier layer 115d can be substantially flat. In some embodiments, the interface between gate contact via 167 and barrier layer 115d can be curved. In some embodiments, a horizontal cross section of gate contact via 167 can have a rectangular shape or a cylindrical shape. In some embodiments, gate contact via 167 can have a tapered shape with a width of a top surface greater than a width of a bottom surface. In some embodiments, gate contact via 167 can have a uniform width from its top surface to its bottom surface. In some embodiments, the width of the top surface of gate contact via 167 can be between about 2 nm and about 40 nm. In some embodiments, a height of gate contact via 167 can be between about 10 nm and about 50 nm. In some embodiments, an aspect ratio of gate contact via 167 can be between about 2:1 and about 20:1. In some embodiments, if the aspect ratio of gate contact via 167 is less than about 2:1, the width of gate contact via 167 may exceed a width of gate electrode 115c and interfere with surrounding contact structures. In some embodiments, if the aspect ratio of gate contact via 167 is greater than about 20:1, gate contact via 167 may be too narrow and may have a high resistance. In some embodiments, gate contact via 167 can include metals with low resistivity such as tungsten, cobalt, and/or ruthenium.

Referring to FIG. 1A, transistor 105 of semiconductor device 100 can further include S/D epitaxial structures 125 disposed over opposite sides (e.g., along the x-direction) of each NS layer 120 to function as transistor 105's source and drain terminals. S/D epitaxial structures 125 can be disposed on fin structures 110. In some embodiments, S/D epitaxial structures 125 can be disposed on fin structures 110. S/D epitaxial structures 125 can be made of an epitaxially-grown semiconductor material similar to (e.g., lattice mismatch within about 5%) NS layers 120. In some embodiments, S/D epitaxial structures 125 can be made of Si, Ge, SiGe, InGaAs, or GaAs. S/D epitaxial structures 125 can be doped with p-type dopants, n-type dopants, or intrinsic dopants. In some embodiments, S/D epitaxial structures 125 can have a different doping type from NS layers 120. In some embodiments, the n-type dopants in S/D epitaxial structures 125 can include P, As, Sb, or a combination thereof. In some embodiments, a crystal orientation of S/D epitaxial structures 125 can be the same as the crystal orientation of NS layers 120.

Referring to FIG. 1A, semiconductor device 100 can include inner spacer structures 130 abutting (or in contact with) side surfaces of gate structures 115. Inner spacer structures 130 can separate gate structures 115 from S/D epitaxial structures 125. For example, inner spacer structures 130 can be formed at gate structures 115's opposite sides along transistors 105's channel direction (e.g., along the x-direction) to separate gate structures 115 from S/D epitaxial structures 125. In some embodiments, inner spacer structures 130 can be formed between two vertically (e.g., in the z-direction) adjacent NS layers 120. In some embodiments, inner spacer structures 130 can be formed between fin structures 110 and the bottommost NS layer 120. In some embodiments, inner spacer structures 130 can be formed between mask layer 140 and the topmost NS layer 120. In some embodiments, inner spacer structures 130 can include a silicon-based dielectric, such as silicon nitride (SiN), silicon oxy-carbon-nitride (SiOCN), silicon carbon-nitride (SiCN), or silicon oxy-nitride (SiON). In some embodiments, inner spacer structures 130 can include a low-k material, such as a porous material and a carbon-rich silicon oxide based dielectrics.

Referring to FIG. 1A, semiconductor device 100 can further include gate spacers 135 formed between gate structure 115 and S/D epitaxial structure 125. Gate spacers 135 can provide structural support during the formation of gate structures 115. In addition, gate spacers 135 can provide gate structures 115 with electrical isolation and protection during the formation of S/D contacts. Gate spacers 135 can be made of any suitable dielectric material. In some embodiments, gate spacers 135 can be made of silicon oxide, silicon nitride, or a low-k material with a dielectric constant less than about 3.9. In some embodiments, gate spacers 135 can have any suitable thickness, such as from about 5 nm to about 15 nm. Based on the disclosure herein, other materials and thicknesses for gate spacers 135 are within the scope and spirit of this disclosure.

Referring to FIG. 1A, semiconductor device 100 can further include shallow trench isolation (STI) regions 138 configured to provide electrical isolation between fin structures 110. STI regions 138 can also provide electrical isolation between transistor 105 and neighboring active and passive elements integrated with or deposited on substrate 102. STI regions 138 can include one or more layers of dielectric material, such as a nitride layer, an oxide layer disposed on the nitride layer, and an insulating layer disposed on the nitride layer. In some embodiments, the insulating layer can include silicon oxide, silicon nitride, silicon oxynitride, fluorine-doped silicate glass (FSG), a low-k dielectric material, and/or other suitable insulating materials. Based on the disclosure herein, other dielectric materials for STI regions 138 are within the scope and spirit of this disclosure.

Referring to FIG. 1A, semiconductor device 100 can further include interlayer dielectric (ILD) layers 165 to provide electrical isolation to structural elements such as gate structures 115 and S/D epitaxial structures 125. In some embodiments, gate spacers 135 can be disposed between gate structures 115 and ILD layers 165. ILD layers 165 can include any suitable dielectric material to provide electrical insulation, such as silicon oxide, silicon dioxide, silicon oxycarbide, silicon oxynitride, silicon oxy-carbon nitride, and silicon carbonitride. ILD layers 165 can have any suitable thickness, such as from about 50 nm to about 200 nm, to provide electrical insulation. Based on the disclosure herein, other insulating materials and thicknesses for ILD layers 165 are within the scope and spirit of this disclosure. Referring to FIG. 1A, semiconductor device 100 can further include S/D contacts 163 in contact with S/D epitaxial structures 125. S/D contacts 163 can be disposed on S/D epitaxial structures 125 and surrounded by ILD layers 165. In some embodiments, silicide layers 164 can be disposed between S/D contacts 163 and S/D epitaxial structures 125. In some embodiments, a height of S/D contacts 163 can be between about 10 nm and about 50 nm. S/D contacts 163 can include any suitable conductive material that provides low contact resistance with S/D epitaxial structures 125. In some embodiments, S/D contacts 163 can be made of polysilicon, titanium nitride, tantalum nitride, tungsten nitride, titanium, cobalt, aluminum, copper, tungsten, tantalum, nickel, or a combination thereof. Based on the disclosure herein, other materials for S/D contacts 163 are within the scope and spirit of this disclosure.

Referring to FIGS. 1A and 1B, semiconductor device 100 can further include a dielectric layer 152 on transistors 105. In some embodiments, dielectric layer 152 can include silicon oxide and/or silicon nitride. In some embodiments, dielectric layers 152 can be an etch stop layer. In some embodiments, S/D contacts 163 and gate contact via 167 can extend vertically through dielectric layer 152.

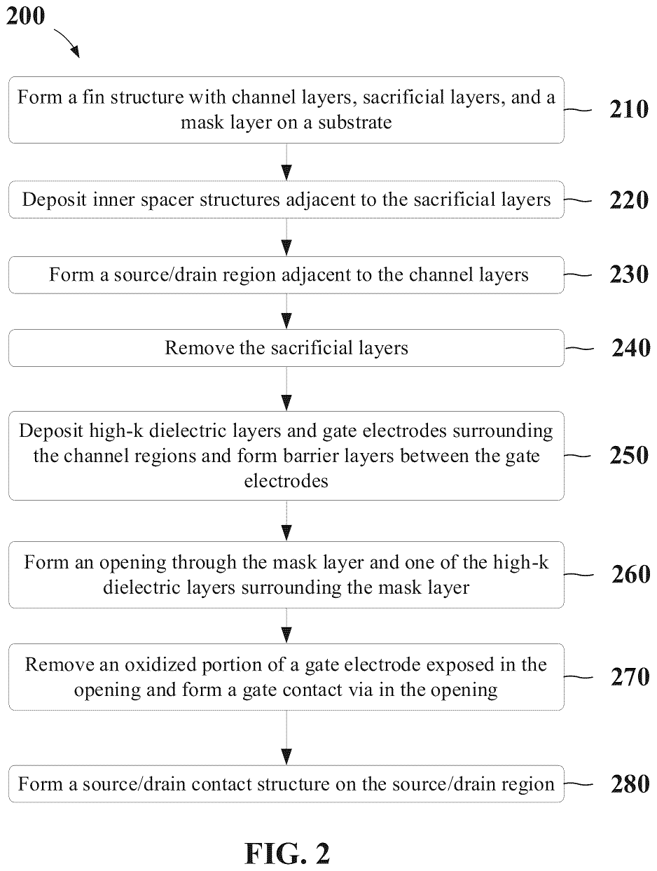

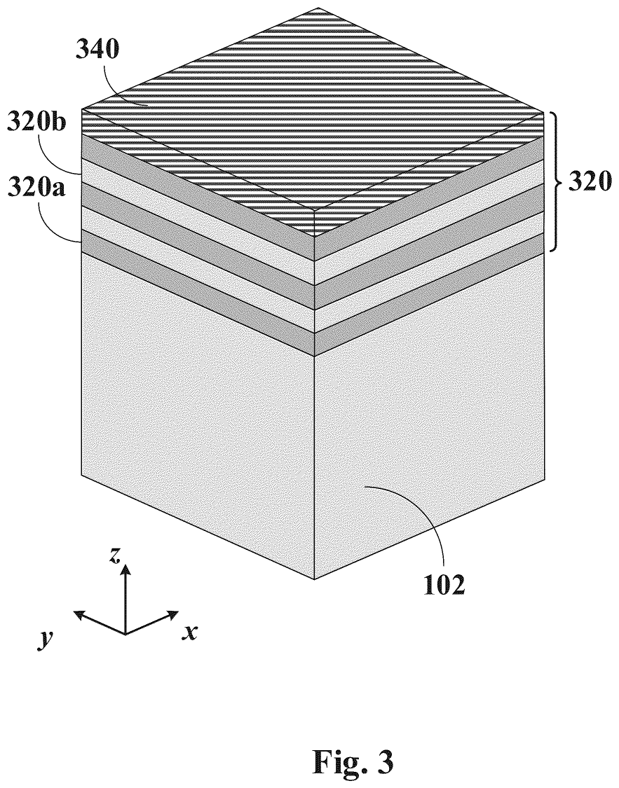

According to some embodiments, FIG. 2 illustrates a flowchart of a fabrication method 200 for the formation of transistors 105 shown in FIGS. 1A-1C. This disclosure is not limited to this operational description and additional operations may be performed. Other fabrication operations can be performed between the various operations of method 200 and are omitted merely for clarity. Moreover, not all operations may be needed to perform the disclosure provided herein. Additionally, some of the operations may be performed simultaneously, or in a different order than the ones shown in FIG. 2. In some embodiments, one or more other operations may be performed in addition to or in place of the presently described operations. For illustrative purposes, method 200 is described with reference to the structures shown in FIGS. 3-13B. The discussion of elements in FIGS. 1A-1C with the same annotations applies to FIGS. 3-13B, unless mentioned otherwise.

Referring to FIG. 2, method 200 begins with operation 210 and the process of forming a fin structure with channel layers, sacrificial layers, and a mask layer on a substrate (e.g., substrate 102). In some embodiments, the process of forming the fin structures can include forming a stack of alternating first and second NS layers on the substrate, FIG. 3 is an isometric view of substrate 102 and the formation of a stack 320 including alternating first and second NS layers 320a and 320b covered by a mask layer 340. In some embodiments, first and second NS layers 320a and 320b are formed on an exposed top surface of substrate 102. In some embodiments, first NS layers 320a are sacrificial NS layers subject to subsequent removal and second NS layers 320b correspond to NS layers 120 shown in FIGS. 1A-1C. In some embodiments, mask layer 340 corresponds to mask layer 140 shown in FIGS. 1A-1C. In some embodiments, the material of first NS layers 320a in stack 320 is selected so that first NS layers 320a can be selectively removed via etching from stack 320 without removing second NS layers 320b and mask layer 340. For example, first NS layers 320a can be SiGe NS layers and second NS layers 320b can be Si NS layers.

First and second NS layers 320a and 320b can be grown with any suitable method. For example, first and second NS layers 320a and 320b can be grown with a chemical vapor deposition (CVD) process with precursor gases, like silane (SiH₄), disilane (Si₂H₆), dichlorosilane (SiH₂Cl₂), trichlorosilane (SiHCl₃), germane (GeH₄), digermane (Ge₂H₆), other suitable gases, or combinations thereof. In some embodiments, first NS layers 320a can include Ge with a concentration between about 20% and about 30%, while second NS layers 320b are substantially germanium-free—e.g., have a Ge concentration less than about 1%. In some embodiments, second NS layers 320b, which correspond to NS layers 120 in FIG. 1A and B, form the channel layers of transistor 105 and can be lightly doped or intrinsic (e.g., un-doped). If lightly doped, the doping level of second NS layers 320b is less than about 10¹³ atoms/cm³. First and second NS layers 320a and 320b can be sequentially deposited without a vacuum break (e.g., in-situ) to avoid the formation of any intervening layers. In some embodiments, first NS layers 320a can be doped to increase their etching selectivity compared to second NS layers 320b in a subsequent etching operation.

In some embodiments, a thickness of first NS layers 320a defines the spacing between every other second NS layer 320b in stack 320. The thickness of second NS layers 320b can range, for example, from about 3 nm to about 15 nm. The thickness of first NS layers 320a can range, for example, from about 3 nm to about 30 nm. The thickness of first NS layers 320a corresponds to vertical spacing H1 between NS layers 120 and vertical spacing H2 between the topmost NS layer 120 and mask layer 140 as shown in FIG. 1C. Since first and second NS layers 320a and 320b are grown individually, the thickness of each NS layer can be adjusted independently based, for example, on the deposition time. In some embodiments, additional or fewer number of first and second NS layers 320a and 320b can be formed in stack 320. In some embodiments, a total number of NS layers can be 2n+1, where n+1 is the number of first NS layers 320a and n is the number of second NS layers 320b in stack 320. In some embodiments, n can be 1, 2, 3, 4, 5, 6, or any integer number greater than 6.

In some embodiments, mask layer 340 can be formed by depositing a layer of dielectric material, such as silicon oxide, silicon nitride, or a low-k material with a dielectric constant less than about 3.9, on a topmost first NS layers 320a. In some embodiments, the dielectric material is selected to be resistive to the subsequent etching process that removes first NS layers 320a. In some embodiments, the layer of dielectric material can be deposited by with a CVD process, an atomic layer deposition (ALD) process, a physical vapor deposition (PVD) process, a sputtering process, or an evaporation process.

Referring to FIG. 2, operation 210 can further include a process of patterning stack 320 to form the fin structures. In some embodiments, stack 320 is patterned to form the fin structures with a width along the y-direction and a length along the x-direction. The width along the y-direction corresponds to width Wc as shown in FIG. 1C. The fin structures can be formed by patterning with any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. In some embodiments, a sacrificial layer is formed over stack 320 and patterned using a photolithography process. Spacers are formed alongside the patterned sacrificial layer using a self-aligned process. The sacrificial layer is then removed, and the remaining spacers may then be used as masking structures to pattern the fin structures.

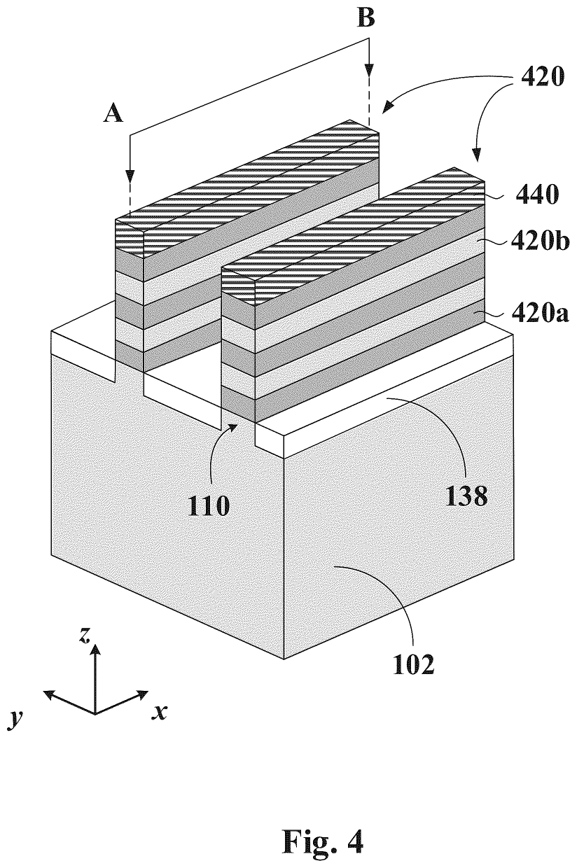

By way of example and not limitation, FIG. 4 is an isometric view of fin structures 420 formed from stack 320 with the aforementioned patterning process. In some embodiments, fin structures 420 can be formed by etching first and second NS layers 320a and 320b and mask layer 340 into first and second NS layers 420a and 420b and a mask layer 440. In some embodiments, the aforementioned patterning process does not terminate on the top surface of substrate 102 but continues to etch a top portion substrate 102 to form fin structures 110 from substrate 102 under fin structures 420. Since fin structures 420 and fin structures 110 are formed with the same patterning process, fin structures 420 and fin structures 110 are substantially aligned to each other. For example, sidewall surfaces of fin structures 420 in the x-z plane and y-z plane are substantially aligned to respective sidewall surfaces of fin structures 110 as shown in FIG. 4.

Additional fin structures, like fin structures 420, can be formed on substrate 102 in the same or different area of substrate 102. These additional fin structures are not shown in FIG. 4 for simplicity. By way of example and not limitation, each fin structure 420 has a width along the y-direction between about 15 nm and about 150 nm.

In some embodiments, NS layers 420a and 420b are referred to as “nano-sheets” when their width along the y-direction is substantially different from their height along z-direction—for example, when their width is larger/narrower than their height. In some embodiments, NS layers 420a and 420b can also be referred to as “nano-wires” when their width along the y-direction is substantially equal to their height along z-direction. In some embodiments, NS layers 420a and 420b are deposited as nano-sheets and subsequently patterned to form nano-wires with substantially equal height and width. By way of example and not limitation, NS layers 420a and 420b will be described in the context of nano-sheets (NS) layers. Based on the disclosure herein, nano-wires (NW) are within the spirit and the scope of this disclosure. Further, for example purposes and without limiting the scope of this disclosure, first and second NS layers 420a and 420b in method 200 will be described in the context of SiGe and Si NS layers, respectively.

In some embodiments, after the formation of fin structures 420, STI regions 138 can be formed on etched or recessed portions of substrate 102 to cover sidewall surfaces of fin structures 110. In some embodiments, STI regions 138 can include one or more silicon oxide based dielectrics that electrically isolate fin structures 110. By way of example and not limitation, STI regions 138 can be formed as follows. An isolation structure material (e.g., a silicon oxide based dielectric) is blanket deposited over fin structures 420 and substrate 102. The as-deposited isolation structure material is planarized (e.g., with a chemical mechanical polishing (CMP) process) so that the top surface of the isolation structure material is substantially coplanar with the top surface of fin structures 420. The planarized isolation structure material is subsequently etched back so that the resulting STI regions 138 has a height substantially similar to fin structures 110, as shown in FIG. 4. In some embodiments, fin structures 420 protrudes from STI regions 138 so that STI regions 138 does not cover sidewall portions of fin structures 420 as shown in FIG. 4.

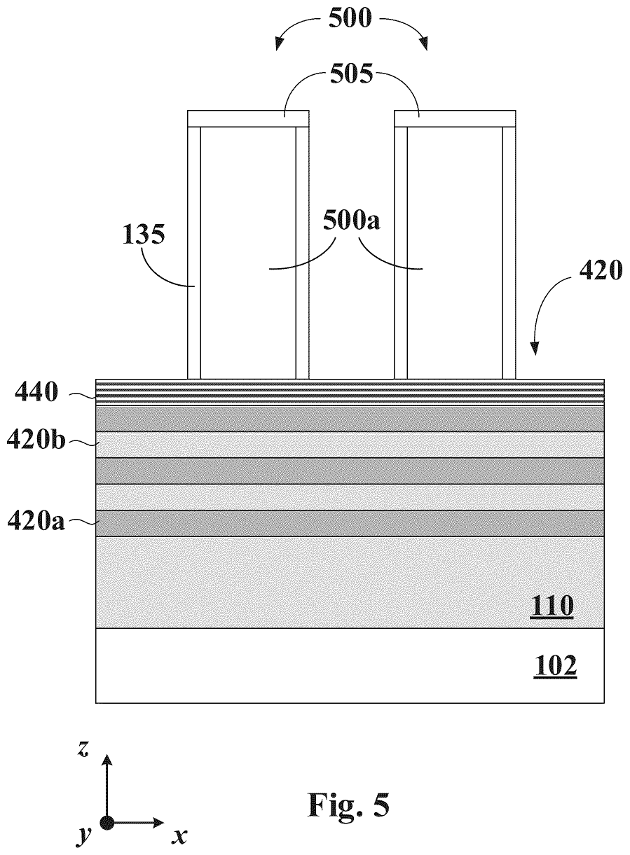

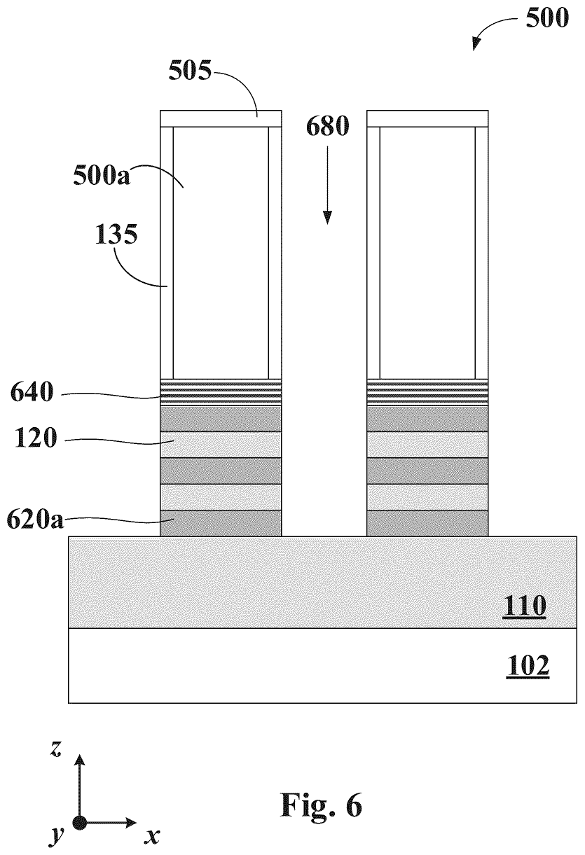

Method 200 continues with operation 220 and the process of forming inner spacers in the fin structure. Operation 220 can start with removing portions of the fin structures to form openings in the fin structures, including (i) forming sacrificial gate structures 500, as described with reference to FIG. 5 and (ii) removing the portions of fin structure 420 exposed by sacrificial gate structures 600, as described with reference to FIG. 6.

By way of example and not limitation, FIG. 5 is a cross-sectional view of FIG. 4 along cut-line AB. FIG. 5 shows sacrificial gate structures 500 formed on portions of fin structures 420. Because FIG. 5 is a cross-sectional view, as opposed to an isometric view, portions of sacrificial gate structures 500 covering sidewall portions of fin structures 420 are not shown. Further, in the cross-sectional view of FIG. 5, only one of fin structures 420 from FIG. 4 is shown. In some embodiments, portions of sacrificial gate structures 500 are formed between fin structures 420 and on STI regions 138 shown in FIG. 4.

In some embodiments, sacrificial gate structures 500 are formed with their length along the y-direction—e.g., perpendicular to fin structures 420 shown in the isometric view of FIG. 4—and their width along the x-direction. In some embodiments, sacrificial gate structures 500 can cover top and sidewall portions of fin structures 420. Sacrificial gate structures 500 are subsequently replaced with gate structures 115 shown in FIGS. 1A-1C during a subsequent gate replacement process. Sacrificial gate structures 500 can include a sacrificial gate electrode 500a formed on mask layer 440. Sacrificial gate structures 500 can also include capping layers 505 formed on top surfaces of sacrificial gate structures 500. In some embodiments, capping layers 505 can protect sacrificial gate electrode 500a from subsequent etching operations. At this fabrication stage, gate spacers 135 can be formed on side surfaces of sacrificial gate structures 500. As discussed above, gate spacers 135 are not removed during the gate replacement process; instead, gate spacers 135 facilitate the formation of gate structures 115 as shown in FIG. 1A.

By way of example and not limitation, sacrificial gate structures 500 can be formed by depositing and patterning sacrificial gate electrode 500a over fin structures 420. In some embodiments, sacrificial gate structures 500 are formed over multiple fin structures 420. As shown in FIG. 5, portions of fin structures 420 are not covered by sacrificial gate structures 500. This is because the width of sacrificial gate structures 500 is narrower than the length of fin structures 420 along the x-direction. In some embodiments, sacrificial gate structures 500 are used as masking structures in subsequent etching operations to define the channel regions of transistors 105 shown in FIG. 1A. For this reason, the lateral dimensions (e.g., the width and length) of sacrificial gate structures 500 and gate structures 115 are substantially similar.

Referring to FIG. 6, portions of fin structures 420 not covered by sacrificial gate structures 500 can be removed to form openings 680. In some embodiments, the removal process involves a dry etching process, a wet etching process, or combinations thereof. The removal process is selective towards mask layer 440, first NS layers 420a and second NS layers 420b, shaping them into mask layer 640, first NS layers 620a and NS layers 120, respectively. In some embodiments, the dry etching process includes etchants having an oxygen-containing gas, a fluorine-containing gas (e.g., carbon tetrafluoride (CF₄), sulfur hexafluoride (SF₆), difluoromethane (CH₂F₂), trifluoromethane (CHF₃), and/or hexafluoroethane (C₂F₆)); a chlorine-containing gas (e.g., chlorine (Cl₂), chloroform (CHCl₃), carbon tetrachloride (CCl₄), and/or boron trichloride (BCl₃)); a bromine-containing gas (e.g., hydrogen bromide (HBr) and/or bromoform (CHBr₃)); an iodine-containing gas; other suitable etching gases and/or plasmas; or combinations thereof. The wet etching chemistry can include diluted hydrofluoric acid (DHF), potassium hydroxide (KOH) solution, ammonia; a solution containing hydrofluoric acid (HF), nitric acid (HNO₃), acetic acid (CH₃COOH); or combinations thereof.

In some embodiments, the etchants of the aforementioned etching process do not substantially etch sacrificial gate structures 500—which is protected by capping layers 505 and gate spacers 135—and STI regions 138 shown in FIG. 6. This is because capping layers 505, gate spacers 135, and STI regions 138 include materials with a low etching selectivity, such as a silicon nitride based material (e.g., silicon nitride, silicon carbon nitride, and silicon carbon oxy-nitride) or silicon oxide based materials. In some embodiments, STI regions 138 shown in FIG. 6 are used as an etch stop layer for the etching process described above.

After removing the portions of fin structures 420 not covered by sacrificial gate structures 500, openings 680 are formed in each fin structure 420 as shown in FIG. 6. Openings 680 divide each fin structure 420 into separate portions, with each portion covered by a sacrificial gate structure 500.

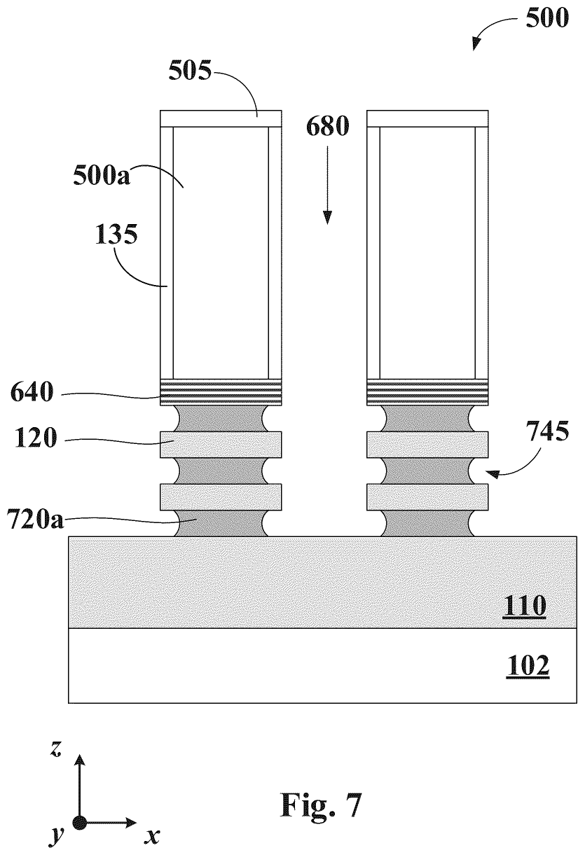

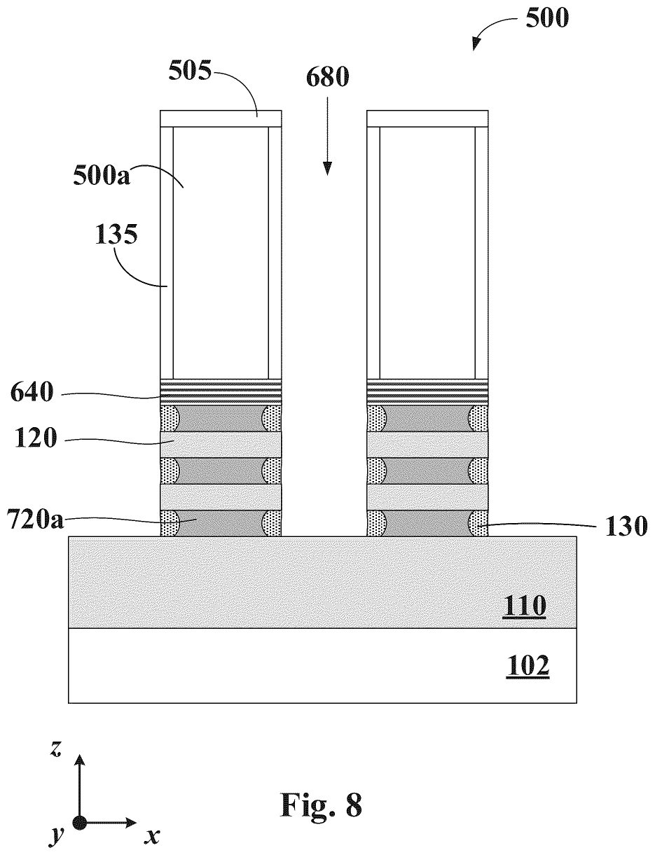

Referring to FIG. 2, operation 220 can continue with a process of forming inner spacers in openings 680. The process of forming inner spacers can include (i) selectively etching edge portions of first NS layers 620a to form recess structures 745, as described with reference to FIG. 7 and (ii) forming inner spacer structures 130 in recess structures 745, as described with reference to FIG. 8. According to some embodiments, FIG. 7 shows the structure of FIG. 6 after exposed edges of first NS layers 620a are laterally etched (e.g., recessed) along the x-direction and turned into first NS layers 720a. According to some embodiments, exposed edges of first NS layers 620a are recessed (e.g., partially etched) by an amount that ranges from about 3 nm to about 10 nm along the x-direction as shown in FIG. 7 to form recesses structures 745.

In some embodiments, the selective etching of first NS layers 620a can be achieved with a dry etching process selective towards SiGe. For example, halogen-based chemistries exhibit a high etching selectivity towards Ge and a low etching selectivity towards Si. Therefore, halogen gases etch Ge-containing layers, such as first NS layers 620a, at a higher etching rate than substantially Ge-free layers like NS layers 120. In some embodiments, the halogen-based chemistries include fluorine-based and/or chlorine-based gasses. Alternatively, a wet etching chemistry with high selectivity towards SiGe can be used. By way of example and not limitation, a wet etching chemistry may include a mixture of sulfuric acid (H₂SO₄) and hydrogen peroxide (H₂O₂) (SPM), or a mixture of ammonia hydroxide with H₂O₂ and water (APM). The aforementioned etching processes are timed so that the desired amount of SiGe is removed.

In some embodiments, first NS layers 620a with a higher Ge atomic concentration have a higher etching rate than NS layers 120 with a lower or zero Ge atomic concentration. Therefore, the etching rate of the aforementioned etching processes can be adjusted by modulating the Ge atomic concentration (e.g., the Ge content) in first NS layers 620a. As discussed above, the Ge content in first NS layers 620a can range between about 20% and about 30%. A SiGe nano-sheet layer with about 20% Ge can be etched slower than a SiGe nano-sheet layer with about 30% Ge. Consequently, the Ge concentration can be adjusted accordingly to achieve the desired etching rate and selectivity between first NS layers 620a and NS layers 120.

Referring to FIGS. 7 and 8, once recessed structures 745 are formed, a dielectric layer can be blanket deposited over the entire structure of FIG. 7, and the portion of the dielectric layer outside recess structures 745 can be removed, leaving inner spacer structures 130 behind filling recessed structures 745, as described with reference to FIG. 8.

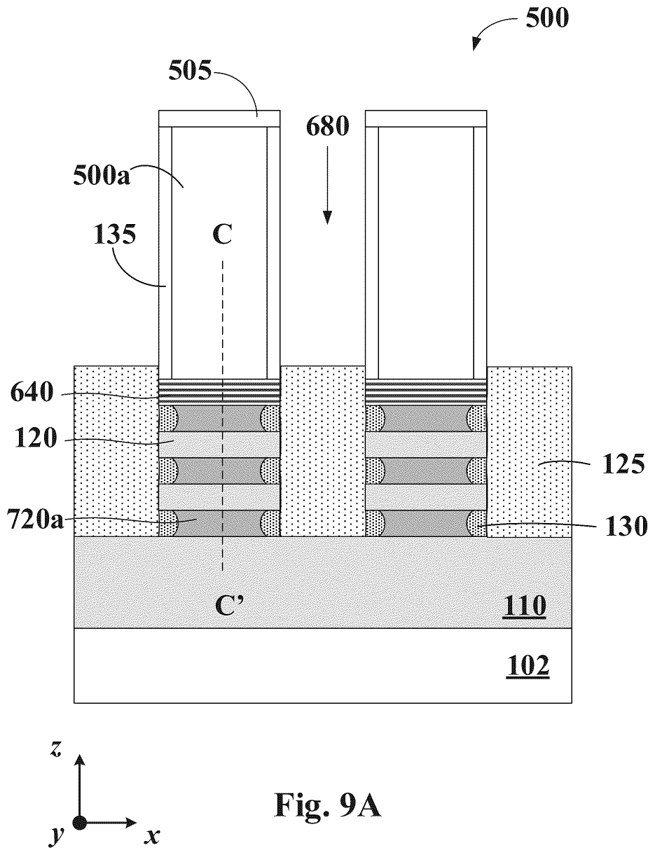

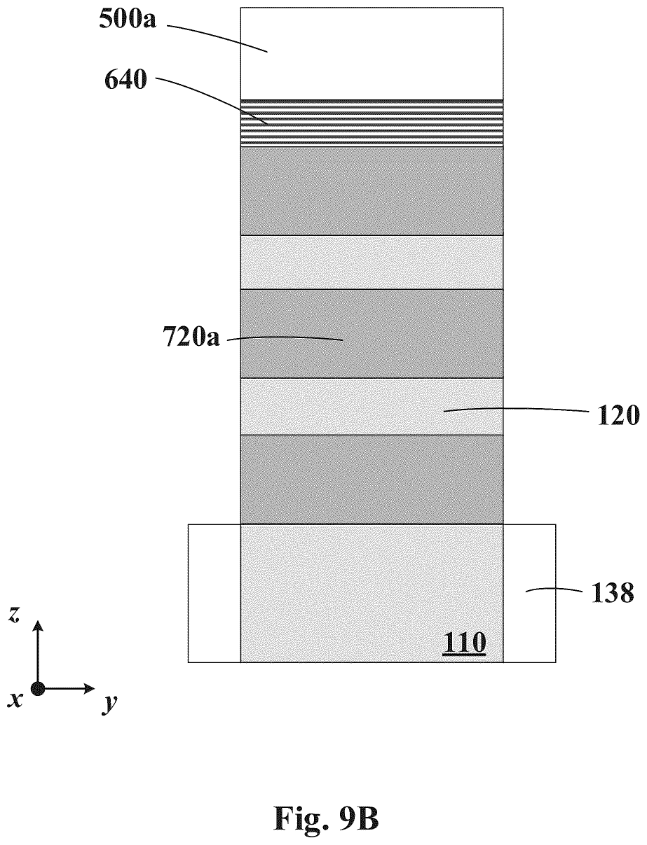

Referring to FIG. 2, after forming inner spacer structures 130, method 200 can continue with operation 230 and a process of forming S/D epitaxial structures in openings 680 and adjacent to NS layers 120. For example, as described with reference to FIG. 9A, S/D epitaxial structures 125 can be formed by epitaxially growing a semiconductor material in openings 680.

In some embodiments, as described with reference to FIG. 9A, S/D epitaxial structures 125 can be epitaxially grown with a CVD process similar to the one used in operation 210 to form first and second NS layers 320a and 320b, as described with reference to FIG. 3. In some embodiments, S/D epitaxial structures 125 can be epitaxially grown on side surfaces of NS layers 120 in a horizontal direction (e.g., along the x-axis). In some embodiments, S/D epitaxial structures 125 can be epitaxially grown on top surfaces of fin structure 110 in a vertical direction (e.g., along the z-axis). In some embodiments, S/D epitaxial structures 125 can be grown using a plasma-enhanced CVD (PECVD) process. In some embodiments, precursor gases (e.g., SiH₄, SiH₂Cl₂, SiHCl₃, or a combination thereof) can be used to grow a semiconductor material (e.g., Si) having a crystalline structure the same as or similar to the crystalline structure of NS layers 120. In some embodiments, etching gases (e.g., hydrogen chloride (HCl)) can be used to selectively remove the semiconductor material with an amorphous structure formed on dielectric surfaces (e.g., side surfaces of inner spacer structures 130 and gate spacers 135). Removing the semiconductor material with the amorphous structure can ensure that the crystal structure of S/D epitaxial structures 125 is crystalline. In some embodiments, dopant precursor gases, such as phosphanes (PH₃), arsanes (AsH₃), stibane (SbH₃), or a combination thereof can be used in the CVD process or the PECVD process to dope S/D epitaxial structures 125.

FIG. 9B illustrates a cross sectional view corresponding to the C-C′ line in FIG. 9A. Note that FIG. 9B represents the same cross sectional view corresponding to the same location among FIGS. 5-9A and is unchanged between operations 220 and 230.

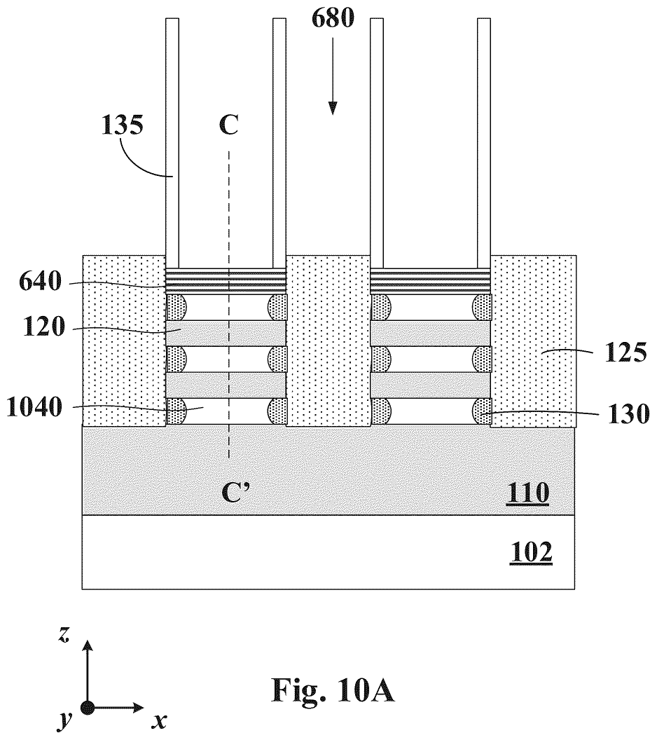

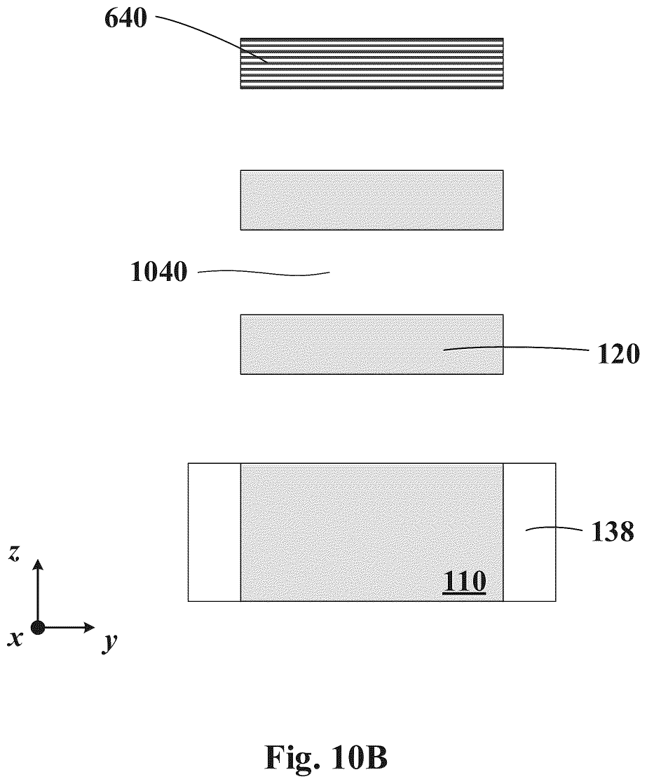

Referring to FIG. 2, method 200 can continue with operation 240 and a process of removing the sacrificial layers. For example, as described with reference to FIGS. 10A and 10B, first NS layers 720a can be removed, together with sacrificial gate structures 500. In some embodiments, removing sacrificial gate structures 500 can include removing capping layer 505 to expose sacrificial gate electrode 500a, and subsequently, removing sacrificial gate electrode 500a to expose a top surface of mask layer 640. In some embodiments, removing first NS layers 720a can include selectively etching first NS layers 720a without removing NS layers 120 and mask layer 640, as described with reference to FIGS. 10A and 10B, such that upper, lower, and side surfaces of NS layers 120 and mask layer 640 can be exposed. In some embodiments, a top surface of fin structure 110 under NS layers 120 can also be exposed.

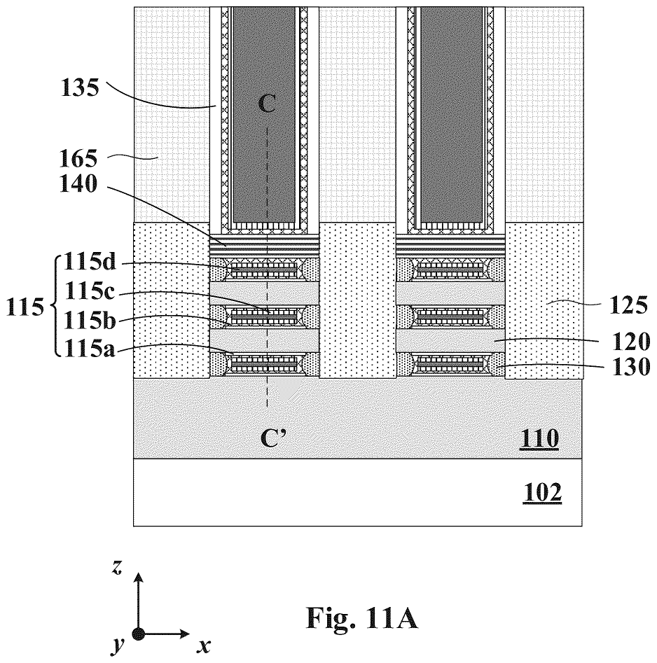

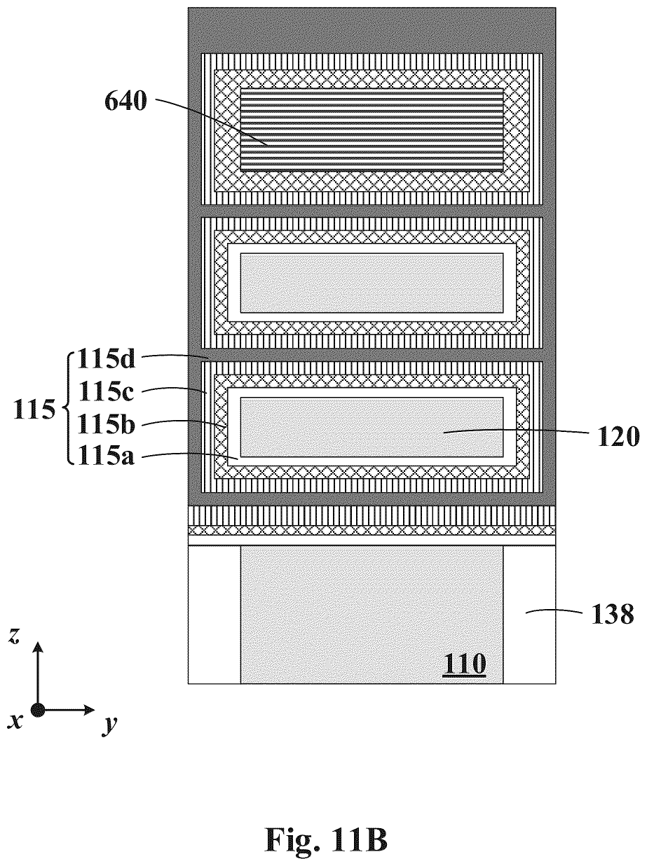

Referring to FIG. 2, method 200 can continue with operation 250 and a process of forming a gate structure, including (i) depositing high-k dielectric layers surrounding the channel layers and the mask layer, (ii) depositing gate electrodes surrounding the high-k dielectric layers, and (iii) forming a barrier layer between the gate electrodes, as described with reference to FIGS. 11A and 11B.

In some embodiments, prior to the deposition of the high-k dielectric layers, interfacial dielectric layers 115a can be formed on the exposed surfaces of NS layers 120. Interfacial dielectric layers 115a can be formed by treating NS layers 120 in an environment with oxygen radicals, such as oxygen gas, ozone, deionized water, deionized water (DI-water), carbonated DI-water (DICO₂), ozonated DI-water (DIO₃), hydrogen peroxide (H₂O₂), sulfuric acid (H₂SO₄), chloric acid (HCl), ammonia (NH₄OH), or a combination thereof. In some embodiments, NS layers 120 can be treated with the oxygen radicals in a thermal process. In some embodiments, interfacial dielectric layers 115a can be formed on the exposed top surface of fin structure 110. In some embodiments, the presence of interfacial dielectric layers 115a can facilitate the subsequent deposition of high-k dielectric layers on NS layers 120.

In some embodiments, the process of forming gate dielectric layers 115b on interfacial dielectric layers 115a can include depositing a high-k dielectric material (e.g., HfO₂, Al₂O₃, ScO₂, ZrO₂, CaO, MgO, and/or ZrSiO₄) in a CVD process or an ALD process. In some embodiments, depositing gate electrodes 115c can include depositing one or more work function metal layers (e.g., TiAlC) in a CVD process or an ALD process. In some embodiments, gate dielectric layer 115b and gate electrodes 115c can also be deposited on the exposed top surface of fin structure 110. Deposition parameters (e.g., a deposition time, a deposition pressure, and/or a deposition temperature) can be selected to control thicknesses of gate dielectric layer 115b and gate electrodes 115c and to ensure that gate electrodes 115c surrounding different NS layers 120 and mask layer 640 do not merge into each other, such that there is sufficient spacing between gate electrodes 115c for the subsequent deposition of barrier layer 115d. In some embodiments, depositing barrier layer 115d can include depositing TiN or TaN in a CVD process or an ALD process to fill the space between gate electrodes 115c. In some embodiments, precursors of titanium chloride (TiClₓ) and/or ammonia (NH₃) can be used for the deposition of barrier layer 115d. In some embodiments, a deposition temperature can be between about 300° C. and about 500° C. In some embodiments, barrier layer 115d can be deposited on side surfaces of gate electrodes 115c to surround gate electrodes 115c. In some embodiments, barrier layer 115d can also be deposited above mask layer 640.

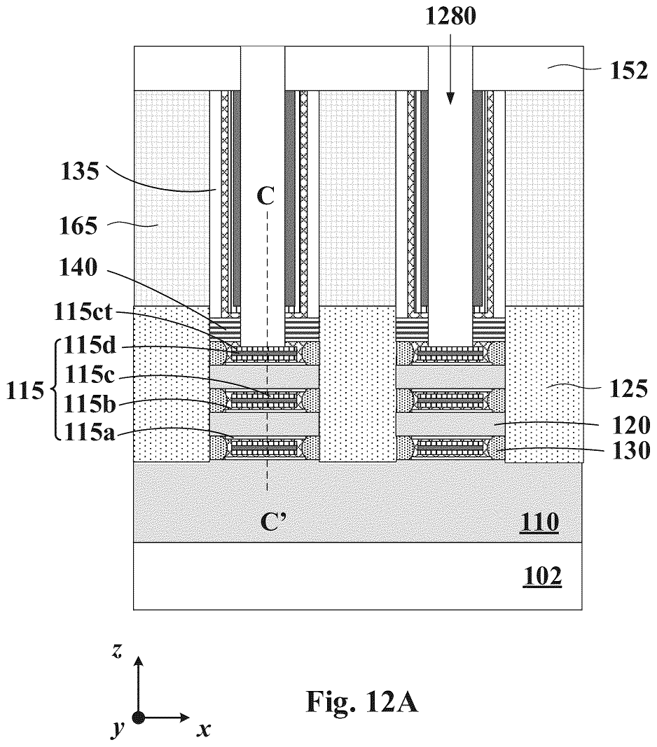

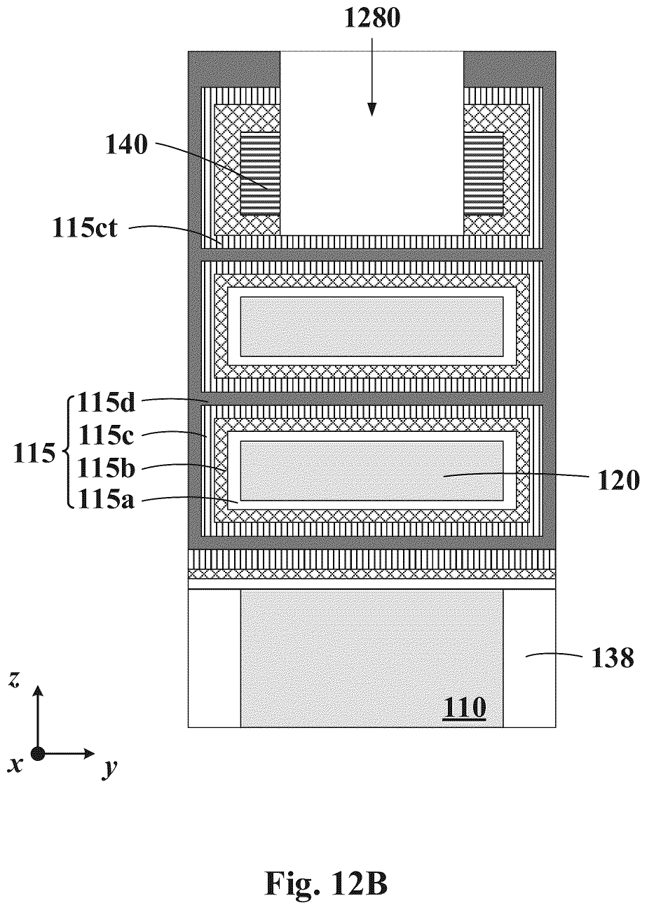

Referring to FIG. 2, method 200 continues with operation 260, in which a contact opening is formed through the mask layer. For example, as described with reference to FIGS. 12A and 12B, a contact opening 1280 can be formed through a portion of barrier layer 115d and an upper portion of a top most gate electrode 115c that are above mask layer 640. In some embodiments, prior to forming contact opening 1280, dielectric layer 152 can be deposited over gate structure 115. Contact opening 1280 can be formed through dielectric layer 152. Contact opening 1280 can also be formed through mask layer 640, turning it into mask layer 140. Contact opening 1280 can also be formed through a topmost gate dielectric layer 115b surrounding mask layer 640 to expose a lower portion 115ct of the topmost gate electrode 115c surrounding mask layer 640. In some embodiments, contact opening 1280 can have a vertical cross-sectional profile with vertical or slanted side surfaces. In some embodiments, contact opening 1280 can have a horizontal cross-sectional profile with a rectangular shape or a circular shape.

In some embodiments, the process of forming contact opening 1280 can include a dry etching process with one or more etchants, such as a fluorine-based etching gas (e.g., tungsten hexafluoride (WF₆) or hydrogen fluoride (HF)). In some embodiments, the fluorine atoms of the etchants can diffuse into the regions under opening 1280, and a concentration of the fluorine atoms can decrease with an increasing diffusion depth. Therefore, a first concentration of the fluorine atoms in a first portion of barrier layer 115d between mask layer 140 and the topmost NS layer 120 can be greater than a second concentration of the fluorine atoms in a second portion of barrier layer 115d between NS layers 120. For example, a ratio between the first and second concentrations of the fluorine atoms can be about 2:1 and about 10:1.

In some embodiments, during formation of contact opening 1240, lower portion 115ct of the topmost gate electrode 115c exposed in contact opening 1240 can be partially or completely oxidized due to the reaction between the etchants and the exposed metallic material (e.g., TiAlC) of gate electrode 115c. The oxidized lower portion 115ct can impact a quality of the contact resistance between gate electrode 115c and a subsequently formed gate contact via, and can be removed in a subsequent operation 270.

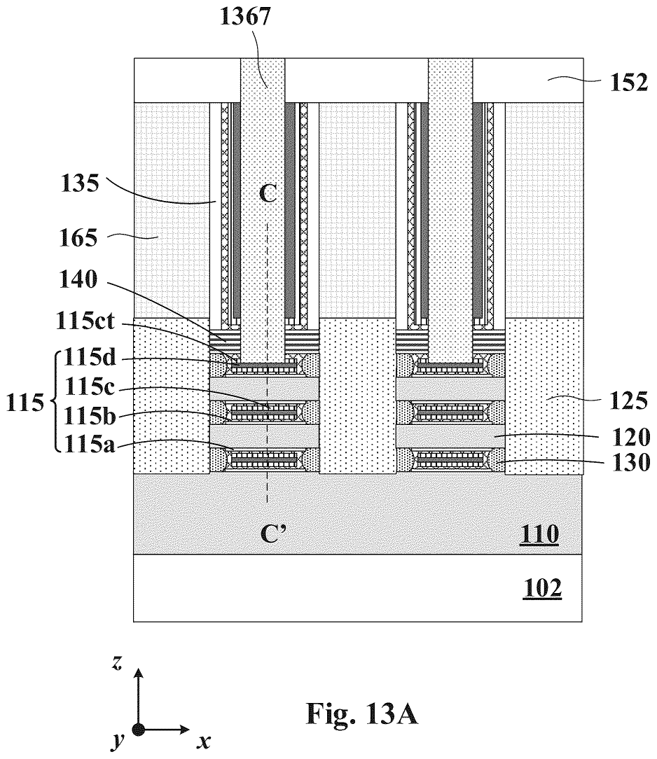

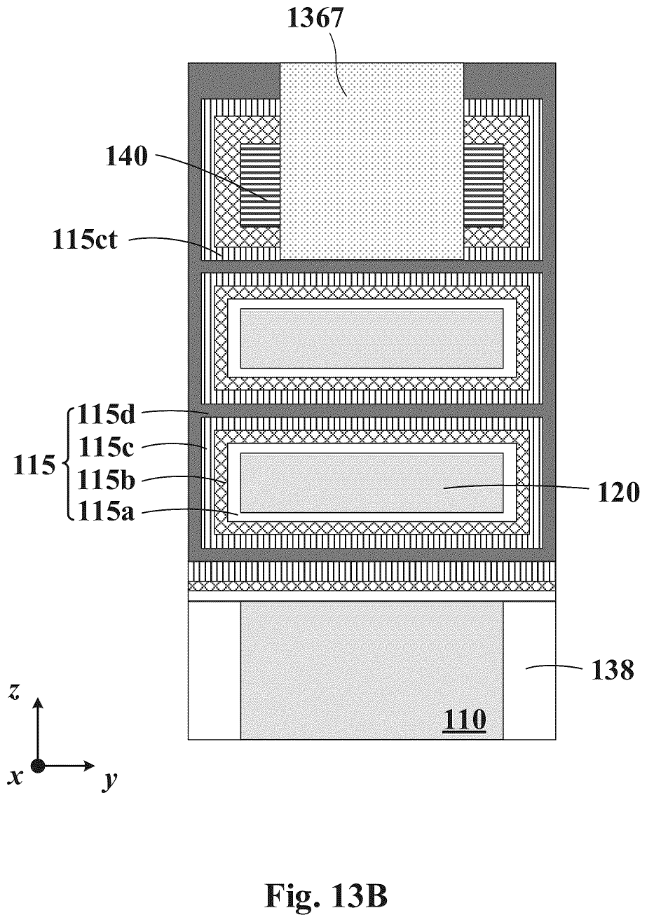

Referring to FIG. 2, method 200 continues with operation 270, in which a gate contact via is formed in the contact opening. For example, as described with reference to FIGS. 13A and 13B, gate contact via 167 can be formed in contact opening 1280. In some embodiments, the process of forming gate contact via 167 can include depositing a layer of metallic material (e.g., metals with low resistivity such as tungsten, cobalt, and/or ruthenium) in a CVD process, using precursors WCl₅ and H₂. In some embodiments, the CVD process can be a cyclic process with precursors WCl₅ and H₂ introduced alternatingly. In some embodiments, the precursors WCl₅/H₂ can remove the oxidized portion of the topmost gate electrode 115c while depositing tungsten on barrier layer 115d. In some embodiments, using the precursors WCl₅/H₂, the deposition of tungsten can be a bottom-up process, such that tungsten can be deposited from the bottom surface of contact opening 1280 but not on its side surfaces, avoiding the formation of overhang or void structures in contact opening 1280. In some embodiments, a deposition temperature can be between about 350° C. and about 500° C. For example, the deposition temperature can be between about 375° C. and about 475° C. In some embodiments, the presence of barrier layer 115d can serve a seed layer that promotes a uniform growth of tungsten. In some embodiments, the CVD process to deposit tungsten to form gate contact via 1367 can be a fluorine-free process. In some embodiments, the absence of fluorine during the deposition of tungsten can promote the uniform growth of tungsten.

Referring to FIG. 2, method 200 can continue with operation 280 and a process of forming S/D contacts 163, as described with reference to FIG. 1A. In some embodiments, the process of forming S/D contacts 163 can include (i) forming ILD layers 165 on S/D epitaxial structures 125 and between gate structures 115, (ii) forming openings through ILD layer 165 to expose S/D epitaxial structures 125, (iii) depositing a metallic material (e.g., W, Cu, and/or Mo) in the openings and in contact with S/D epitaxial structures 125 to forming S/D contacts 163, and (iv) forming a silicide layer 164 between S/D contacts 163 S/D epitaxial structures 125.

The embodiments described herein are directed to a structure of a semiconductor device and a method of forming the structure. The structure can include a GAAFET on a substrate. The GAAFET can include a stack of channel layers and a mask layer on the channel layers. The GAAFET can further include a gate structure and S/D regions. The gate structure can include gate dielectric layers and gate electrodes surrounding each of the channel layers and the mask layer. The gate structure can further include a barrier layer between the gate electrodes surrounding different channel layers and the mask layer. The GAAFET can further include a gate contact via through the mask layer and the topmost gate dielectric layer and the topmost gate electrode that surround the mask layer. The presence of the mask layer can reduce a height of the gate structure and improve a performance of the GAAFET. The method of forming the structure can include forming an opening through the mask layer to expose a portion of the topmost gate electrode surrounding the mask layer and depositing tungsten in the opening to form the gate contact via while removing an oxidized portion of the exposed topmost gate electrode. The presence of the barrier layer can prevent the oxidation of other gate electrodes surrounding the channel layers. The presence of the barrier layer can also promote uniform deposition of tungsten on the barrier layer, hence a high quality of the gate contact via. The removal of the oxidized portion of the exposed topmost gate electrode during the deposition of tungsten can ensure a low contact resistance between the gate contact via and the gate structure.

In some embodiments, a structure includes a nanostructure on a substrate a mask layer on the nanostructure, a first dielectric layer surrounding the nanostructure, a first work function metal layer surrounding the first dielectric layer, a second dielectric layer surrounding the mask layer, a second work function metal layer surrounding the second dielectric layer, a barrier layer between the first and second work function metal layers, and a contact structure through the second dielectric layer, the second work function metal layer, and the mask layer and in contact with the barrier layer.

In some embodiments, a structure includes a fin structure on a substrate and a gate structure on the fin structure. The fin structure includes a nanostructure and a mask layer on the nanostructure. The gate structure includes a dielectric layer surrounding the nanostructure and the mask layer, a work function metal layer surrounding the dielectric layer, and a barrier layer between the nanostructure and the mask layer. The structure further includes a contact structure through the mask layer and in contact with the barrier layer.

In some embodiments, a method includes forming channel layers and sacrificial layers alternatingly on a substrate, forming a mask layer on a topmost sacrificial layer of the sacrificial layers, and forming a fin structure by patterning the channel layers, the sacrificial layers, and the mask layer. The method further includes forming a source/drain (S/D) region adjacent to the fin structure and removing the sacrificial layers. The method further includes depositing a high-k dielectric layer surrounding each of the channel layers, depositing a work function metal layer on the high-k dielectric layer, and depositing a barrier layer on the work function metal layer and between adjacent nanostructures of the nanostructures. The method further includes forming a contact structure through the mask layer and in contact with a portion of the barrier layer under the mask layer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a nanostructure on a substrate;
a mask layer on the nanostructure;
a first dielectric layer surrounding the nanostructure;
a first work function metal layer surrounding the first dielectric layer;
a second dielectric layer surrounding the mask layer;
a second work function metal layer surrounding the second dielectric layer;
a barrier layer between the first and second work function metal layers; and
a contact structure through the second dielectric layer, the second work function metal layer, and the mask layer and in contact with the barrier layer.

2. The structure of claim 1, wherein the barrier layer comprises titanium nitride.

3. The structure of claim 1, wherein the first and second work function metal layers comprise titanium aluminum carbide.

4. The structure of claim 1, wherein the first and second dielectric layers comprise a high-k dielectric material, and wherein the mask layer comprises a low-k dielectric material or silicon nitride.

5. The structure of claim 1, wherein a width of the mask layer is substantially the same as a width of the nanostructure.

6. The structure of claim 1, wherein the contact structure comprises tungsten, cobalt, or ruthenium.

7. The structure of claim 1, further comprising a source/drain region adjacent to the nanostructure.

8. The structure of claim 1, further comprising an inner spacer structure between the nanostructure and the mask layer.

9. A structure, comprising:
a fin structure on a substrate, wherein the fin structure comprises a nanostructure and a mask layer on the nanostructure;
a gate structure on the fin structure and comprising:
a dielectric layer surrounding the nanostructure and the mask layer;
a work function metal layer surrounding the dielectric layer; and
a barrier layer between the nanostructure and the mask layer; and
a contact structure through the mask layer and in contact with the barrier layer.

10. The structure of claim 9, wherein:
a width of the mask layer is substantially the same as a width of the nanostructure; and
a length of the mask layer is substantially the same as a length of the nanostructure.

11. The structure of claim 9, wherein a portion of the barrier layer is above a first portion of the work function metal layer and under a second portion of the work function metal layer.

12. The structure of claim 9, wherein the contact structure extends through a first portion of the work function metal layer above the mask layer and a second portion of the work function metal layer under the mask layer.

13. The structure of claim 9, wherein the contact structure extends through a first portion of the dielectric layer on the mask layer and a second portion of the dielectric layer under the mask layer.

14. A method, comprising:
forming a plurality of channel layers and a plurality of sacrificial layers alternatingly on a substrate;
forming a mask layer on a topmost sacrificial layer of the plurality of sacrificial layers;
forming a fin structure by patterning the plurality of channel layers, the plurality of sacrificial layers, and the mask layer;
forming a source/drain (S/D) region adjacent to the fin structure;
removing the plurality of sacrificial layers;
depositing a high-k dielectric layer surrounding each of the plurality of channel layers;
depositing a work function metal layer on the high-k dielectric layer;
depositing a barrier layer on the work function metal layer and between the mask layer and the plurality of channel layers; and
forming a contact structure through the mask layer and in contact with a portion of the barrier layer under the mask layer.

15. The method of claim 14, wherein depositing the barrier layer comprises depositing a layer of titanium nitride or tantalum nitride.

16. The method of claim 14, wherein depositing the barrier layer comprises depositing the barrier layer on a first horizontal surface of the work function metal layer and under a second horizontal surface of the work function metal layer.

17. The method of claim 14, wherein forming the contact structure comprises using tungsten (V) chloride and hydrogen as precursors to remove an oxidized portion of the work function metal layer while depositing tungsten in contact with the portion of the barrier layer.

18. The method of claim 14, wherein forming the contact structure comprises removing an oxidized portion of the work function metal layer to expose the portion of the barrier layer.

19. The method of claim 14, wherein forming the contact structure comprises forming an opening through an upper portion of the high-k dielectric layer on the mask layer, the mask layer, and a lower portion of the high-k dielectric layer under the mask layer.

20. The method of claim 14, wherein depositing the work function metal layer comprises depositing a layer of titanium aluminum carbide to surround the plurality of channel layers and the mask layer.
